(19) United States
(12) Patent Application Publication
(10) Pub. No.: US 2025/0077349 A1
(43) Pub. Date: Mar. 6, 2025

(54) MEMORY DEVICE ERROR CORRECTION

(71) Applicant: SAMSUNG ELECTRONICS CO., LTD., Suwon-si (KR)

(72) Inventor: Hoyoun Kim, Suwon-si (KR)

(21) Appl. No.: 18/430,287

(22) Filed: Feb. 1, 2024

(30) Foreign Application Priority Data
Sep. 5, 2023 (KR) 10-2023-0117625

(51) Int. Cl. G06F 11/10

(52) U.S. Cl. CPC G06F 11/1068; G06F 11/1016; G06F 11/106

(57) ABSTRACT

A memory device includes a first memory device configured to store a first error correction code of a first size during a first write operation, a second memory device configured to store a second error correction code of a second size, larger than the first size, during a second write operation, and a control logic circuit configured to control the first memory device and the second memory device. The control logic circuit includes an error correction circuit configured to generate one of the first error correction code and the second error correction code for write data according to puncturing option information.

### CROSS-REFERENCE TO RELATED APPLICATION

This application claims the benefit under 35 USC 119 (a) of Korean Patent Application No. 10-2023-0117625 filed on Sep. 5, 2023, in the Korean Intellectual Property Office, the entire disclosure of which is incorporated herein by reference.

### BACKGROUND

Compute Express Link (CXL) is a high-performance interconnect protocol based on open standards that can provide fast data transfer between a central processing unit (CPU), a memory, and an accelerator in a data server system environment. CXL provides advantages such as a high bandwidth, low latency, a memory sharing function, and compatibility with PCI Express (PCIe), and enables efficient data exchange in high-performance computing tasks such as artificial intelligence (AI) and big data.

### SUMMARY

The present disclosure relates to memory device error correction. Some aspects of this disclosure relate to a memory device in which a differential Error Correction Code (ECC) is applied to reduce redundancy, and a method of operating the same.

According to some implementations, a memory device includes a first memory device configured to store a first error correction code of a first size during a first write operation; a second memory device configured to store a second error correction code of a second size, larger than the first size, during a second write operation; and a control logic circuit configured to control the first memory device and the second memory device. The control logic circuit includes an error correction circuit configured to generate one of the first error correction code and the second error correction code for write data according to puncturing option information.

According to some implementations, a memory device includes a first memory device; a second memory device; and a control logic circuit configured to control the first memory device and the second memory device. The control logic circuit includes an error correction circuit configured to generate a punctured error correction code for the first memory device or an original error correction code for the second memory device according to puncturing option information; and a tracking logic configured to track an error rate of data read from the first memory device or the second memory device. The puncturing option information is changed according to the error rate.

According to some implementations, a method of operating a memory device includes receiving write data; setting an error correction code level according to puncturing option information; generating an error correction code for the write data according to the error correction code level; and storing the write data and the error correction code in a memory device corresponding to the error correction code level.

According to some implementations, a computing system includes a system bus; at least one heterogeneous memory device connected to the system bus; and at least one processor connected to the system bus. The at least one heterogeneous memory device changes a level of an error correction code according to puncturing option information.

According to some implementations, a method of operating a heterogeneous memory includes reading data from a low-reliability memory device; performing an error correction operation on the read data; tracking a codeword error (CE) count according to the error correction operation; and moving the data from the low-reliability memory device to a high-reliability memory device when a value of the CE count is greater than or equal to a reference value.

### BRIEF DESCRIPTION OF THE DRAWINGS

The above and other aspects, features, and advantages provided by some implementations according to this disclosure will be more clearly understood from the following detailed description, taken in conjunction with the accompanying drawings.

FIG. 1 is a diagram illustrating an example of a memory device according to some implementations.

FIGS. 2A and 2B are diagrams conceptually illustrating an example of parity puncturing of ECC according to some implementations.

FIGS. 3A and 3B are diagrams illustrating an example of optional ECC puncturing according to some implementations, by way of example.

FIG. 4 is a diagram illustrating an example of an error correction circuit according to some implementations.

FIGS. 5A and 5B are diagrams illustrating an example of a configuration of optional ECC.

FIG. 6 is a diagram illustrating a puncturing option/pattern table according to an error rate according to some implementations.

FIG. 7 is a diagram illustrating an example of a memory device according to some implementations.

FIG. 8 is a flowchart illustrating an example operation of a memory device according to some implementations.

FIG. 9 is a diagram illustrating an example operation of a memory device according to some implementations.

FIG. 10 is a diagram illustrating an example of a computing system according to some implementations.

FIG. 11 is a diagram illustrating an example of a computing system according to some implementations.

FIG. 12 is a diagram illustrating an example of a server system according to some implementations.

### DETAILED DESCRIPTION

Hereinafter, examples will be described with reference to the accompanying drawings.

Generally, when hybrid memory (for example, a structure of volatile and non-volatile memory) is used in a Compute Express Link (CXL) environment, high-reliability error correction code (ECC) is employed to compensate for the relatively low reliability of non-volatile memory. Applying such high-reliability ECC to volatile memory, which typically has higher reliability, may be a waste of resources. For instance, applying long-length Reed-Solomon (RS) codes designed for NAND flash memory to Dynamic Random Access Memory (DRAM) incurs significant overhead.

To provide more efficient error correction, memory devices according to some implementations of the present disclosure may be implemented by applying ECC that considers the reliability characteristics of different memories. The memory devices can reduce redundancy and provide improved system performance by applying punctured ECC to heterogeneous memories (such as tiered or hybrid memories) based on reliability. Here, punctured ECC refers to the removal of parts of an error correction code in specific environments. For example, while an original ECC (also referred to as master ECC) has check bits for all bit positions, a punctured ECC (also referred to as slave ECC) has some check bits removed. Some memory devices of the present disclosure apply the original ECC for non-volatile/slow-access memory and are equipped with multiple puncturing options, enabling the application of punctured ECC to volatile/fast-access memory depending on the Quality of Service (QOS) requirements. For example, memory devices of the present disclosure may apply customized ECC for multiple heterogeneous memories with one ECC block configuration.

Accordingly, memory devices and associated processes according to some implementations of the present disclosure may establish a low-computational-cost ECC configuration for hybrid/tiered memory and provide multiple puncturing options according to system requirements.

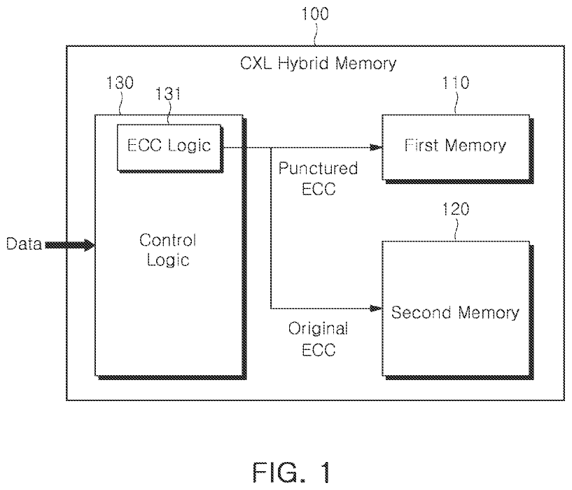

FIG. 1 is a diagram illustrating a memory device 100 according to some implementations. Referring to FIG. 1, the memory device 100 includes a first memory device 110, a second memory device 120, and a control logic circuit 130. In some implementations, the memory device 100 may be a heterogeneous memory device. For example, the memory device 100 may be a Compute Express Link (CXL) hybrid memory device.

The first memory device 110 may be a volatile/fast-access memory device. For example, the first memory device 110 may be implemented as DRAM. In some implementations, the first memory device 110 may apply first ECC having a first size during a first write operation. For example, the first ECC may be a punctured ECC (e.g., a slave ECC). In some implementations, punctured ECC may be an optional ECC in which the length of the parity bit is reduced through code puncturing. In some implementations, the punctured ECC may be the ECC of a level selected from among a plurality of levels corresponding to different ECC. In some implementations, the first size may be variable according to an error rate.

In some implementations, the first ECC may be a 1-bit ECC (e.g., Hamming code), e.g., which may provide relatively weak correction ability. For example, when the weight value of a neural network layer being learned in a machine learning system is stored/updated in DRAM such as the first memory device 110, as long as a significant part of the weight value is accurate, there is little or no hindrance to the progress of learning. As such, an ECC having a first, reduced size may provide sufficient error correction performance. In some implementations, the first ECC is implemented with most significant bit (MSB)-protection code.

The second memory device 120 may be a non-volatile/slow-access memory device. For example, the second memory device 120 may be implemented as non-volatile memory (NVM)/storage class memory (SCM). In some implementations, the second memory device 120 may apply a second ECC with a second size, larger than the first size, during a second write operation. For example, the second ECC may be an original ECC (e.g., a master ECC). In some implementations, the second ECC may be implemented as a symbol ECC (e.g., Reed-Solomon (RS) code, Low-Density Parity Check (LDPC) code, and/or the like) with relatively strong correction ability. In some implementations, the second size may be a fixed value regardless of the error rate.

The control logic circuit 130 may be configured to control the first memory device 110 and the second memory device 120. The control logic circuit 130 may include an error correction circuit 131.

The error correction circuit 131 may be implemented to set the encoder/decoder through puncturing option information. For example, the error correction circuit 131 may perform an operation to change the type of ECC (e.g., RS code, LDPC code, Hamming code, and/or the like) that may be used in the memory device 100 and to change an H matrix (parity check matrix) used in the memory device 100. In some implementations, the error correction circuit 131 may apply ECC to which a first puncturing option is applied to the first memory device 110, and may apply ECC to which a second puncturing option is applied to the second memory device 120. In some implementations, the error correction circuit 131 may change puncturing option information according to an error rate during a memory data read operation. In some implementations, the puncturing option information may be a fixed value.

In some implementations, puncturing option information (e.g., indicating which ECC, ECC type, and/or H matrix is to be used for a given memory) may be set in a register in an initialization operation. In some implementations, puncturing option information may be changed in real-time. In some implementations, puncturing option information may vary according to the error rate of read data. In some implementations, a plurality of puncturing options may exist according to a range of the error rate. In some implementations, the error correction circuit 131 may change the settings of the encoder/decoder according to puncturing option information. In some implementations, the size of the punctured error correction code when reliability takes precedence over operating speed may be larger than the size of the punctured error correction code when operating speed takes precedence over reliability.

In some implementations, the control logic circuit 130 may select a storage location within a heterogeneous memory (hybrid/tiered memory) according to data properties. The control logic circuit 130 may track data that causes errors (e.g., read errors) in low-reliability memory (e.g., using a codeword error (CE) count) and move erroneous data to high-reliability memory during scrubbing.

The memory device 100 can perform parity puncturing according to memory characteristics when applying ECC encoding to write data, and, accordingly, the use of unnecessarily high-performance ECC may be limited, thereby reducing memory overhead. As a result, the overall performance of the memory device 100 may be improved.

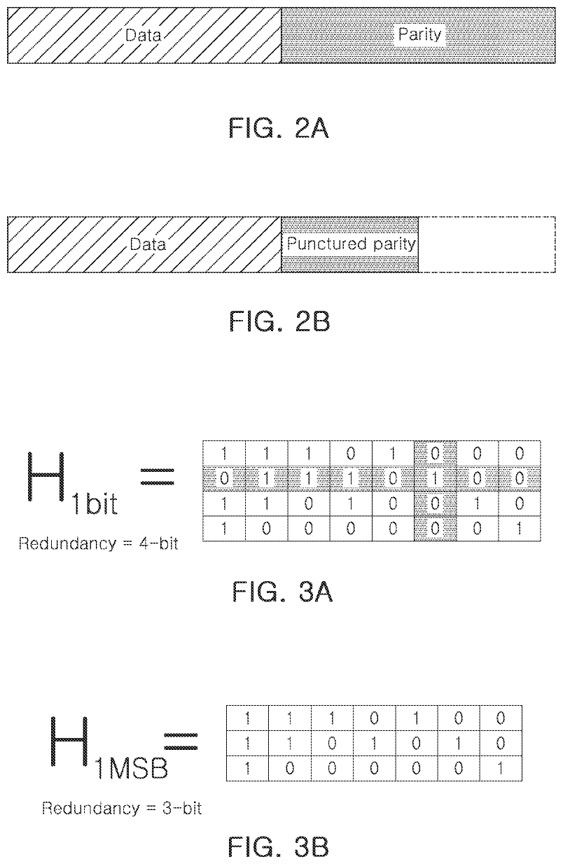

FIGS. 2A and 2B are diagrams conceptually illustrating parity puncturing of ECC according to some implementations. FIG. 2A illustrates the master ECC by way of example, and FIG. 2B illustrates an optional ECC in which the length of the parity bit is reduced through code puncturing in the master ECC. In this case, optional ECC is aimed at configuring low-latency code. FIGS. 2A and 2B illustrate a 2-way ECC configuration through ECC puncturing.

ECC detects/corrects errors when they occur in data being transmitted. An H matrix is a check matrix used in many ECCs. In an error detection operation, the H matrix may determine whether the received data is intact. If the result is not 0 when the H matrix and the received data are multiplied, it is determined that an error has occurred. In error correction operations, some ECCs may use the H matrix to determine the location of an error that occurred and correct the error. In certain situations, not all parity bits may be needed. In this case, unnecessary parity bits may be removed or punctured.

FIGS. 3A and 3B are illustrative diagrams showing optional ECC puncturing according to some implementations of the present disclosure. As depicted in FIG. 3A, an H matrix (H1 bit) with 4-bit redundancy may ensure the correction of a random 1-bit out of 4-bit data. As shown in FIG. 3B, an H matrix (HIMSB) with 3-bit redundancy may guarantee the correction of 1 Most Significant Bit (MSB) within the 4-bit data. Here, the H matrix (HIMSB) may be a matrix modified from the H matrix (H1 bit) through parity puncturing, by removing the shaded column and row from the H matrix (H1 bit).

The error correction circuit 131 may configure ECC puncturing based on the level of redundancy for parity bits provided by the memory. A memory device 100 composed of heterogeneous memories may utilize parity puncturing according to memory characteristics when ECC encoding is applied to write data. When applying ECC within the memory, the length of ECC parity may be adjusted based on memory reliability, thereby limiting the application of unnecessarily high-performance ECC. Consequently, this may lead to performance enhancement due to the reduction of parity (i.e., memory overhead) for data stored in high-reliability memory.

For example, ECC used in neural network applications may be a low-overhead Significant-bit Protection Code. When the weight values of the neural network layer are stored/updated in DRAM, there is little or no reduction in effectiveness in the learning process as long as the significant value of the weight value is accurate. Activation values may also be applied during the inference process. The data precision of neural network weights may be any of 32-bit, 16-bit, or 8-bit. The code may change according to data precision. For example, (136,128)-DRAM ECC may be changed to 4×(32+n1, 32)−ECC or 8×(16+n2, 16)−ECC.

On-die ECC inside DRAM may support Single Error Correction (SEC), Single 2-symbol Error Correction (S2EC), and Single Error Correction, Double Error Detection (SECDED) levels. To correct a 1-bit error at an arbitrary location, approximately 8-bit redundant parity bits are required based on 128-bit data. When four neural network layer weight values are stored in (128+8)-bit data, on-die ECC may correct only one of the four weights. By division into four blocks, it is possible to design a code that may correct the value of the MSB 1-bit of each weight value. For example, (136, 128)-SEC may be changed to (34, 32)-1MSB repetition code×4. Therefore, a significant value may be guaranteed for the four weight values.

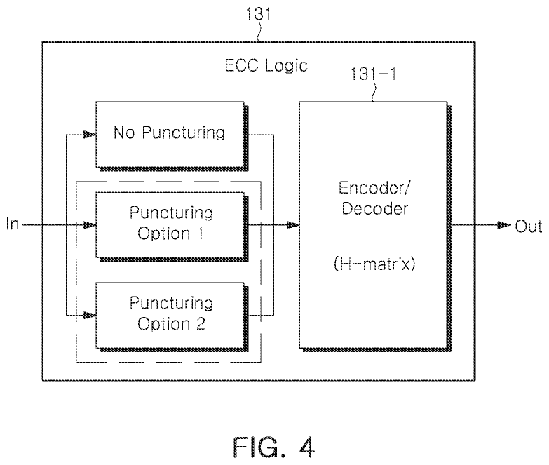

FIG. 4 is a diagram illustrating an error correction circuit 131 according to some implementations. Referring to FIG. 4, the error correction circuit 131 may include an encoder/decoder 131-1.

The error correction circuit 131 may alter the method of generating optional ECC through predefined puncturing options. In this case, the puncturing option can be the H matrix editing option (which row/column to exclude; Option 1), or it can be a configuration change of the encoder/decoder 131-1 dictated by the selected puncturing option (Option 2). At this point, the encoder's puncturing option/pattern may be shared with the decoder.

In some implementations, parity puncturing may remove a portion of the parity/check-bits resulting from ECC encoding. Such parity puncturing may reduce error coverage but may decrease encoding/decoding latency and reduce memory usage. In some implementations, the error correction circuit 131 is capable of adjusting the puncturing level. By configuring the error correction circuit 131 with multiple options (Puncturing Option 1, Puncturing Option 2, etc.), it is possible to reflect user demands and memory specifications. In some implementations, the error correction circuit 131 may identify the destination (e.g., destination memory) using flags/addresses and may apply a dedicated punctured option.

FIGS. 5A and 5B are diagrams illustrating an example of a configuration of optional ECC. The punctured ECC configuration illustrated in FIG. 5A may be applied when reliability is determined to be more important than operating speed. The punctured ECC configuration illustrated in FIG. 5B may be applied when operating speed is determined to be more important than reliability.

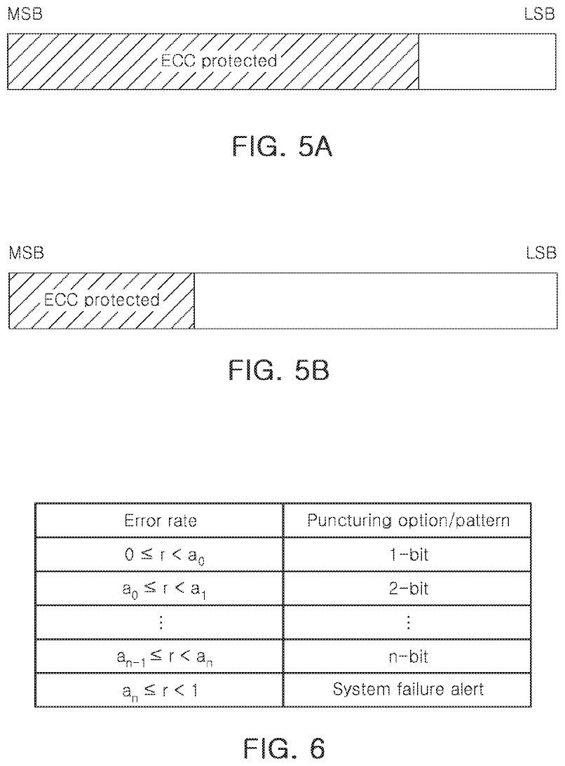

FIG. 6 is a diagram illustratively showing a table of puncturing options/patterns according to the error rate in accordance with some implementations of the present disclosure. Referring to FIG. 6, the values of the puncturing options/patterns may vary depending on a range of an error rate. For instance, when the error rate r is 0 or higher and less than a₀, a 1-bit puncturing option may be applied. When the error rate r is at least a₀ and less than a₁, a 2-bit puncturing option may be employed. If the error rate r is no less than aₙ₋₁ and below aₙ, an n-bit puncturing option may be utilized. When the error rate r is above an and less than 1, a system failure alert may be issued.

In some implementations, when training/testing a DRAM in an initialization operation, the error rate may be measured. Puncturing options may be created and applied according to the measured error rate. In some implementations, when a new tiered memory is connected to the memory system, the internal controller may determine the ECC configuration to be applied.

As illustrated in FIG. 6, puncturing options applied to each region (e.g., die/chip, and/or the like) in which the error rate is determined may be stored in the internal register of the control logic circuit 130 (controller).

The memory device according to some implementations may track the error rate of data read in real-time and change the puncturing option according to the tracked error rate.

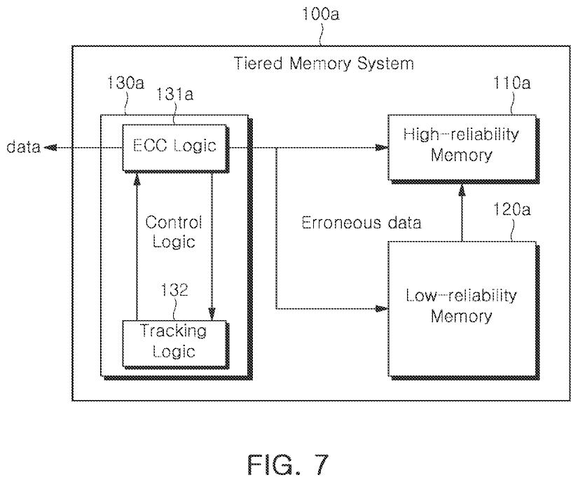

FIG. 7 is a diagram illustrating a memory device 100a according to some implementations. Referring to FIG. 7, the memory device 100a may include a high-reliability memory device 110a, a low-reliability memory device 120a, and a control logic circuit 130a.

In this case, the memory device 100a may communicate with an external device using a Compute Express Link (CXL) interface.

The high-reliability memory device 110a may be implemented to store data along with a punctured error correction code during a write operation. In some implementations, the punctured error correction code may include a Hamming code.

The low-reliability memory device 120a may be implemented to store data along with the original error correction code during a write operation. In some implementations, the original error correction code may be an RS code.

The control logic circuit 130a may include an error correction circuit 131a and tracking logic 132. In some implementations, the control logic circuit 130a may move erroneous data from the low-reliability memory device 120a to the high-reliability memory device 110a based on the error rate.

The error correction circuit 131a may be implemented to change in real-time the puncturing option/level applicable to each memory layer or portion according to the memory error rate. In some implementations, if the error rate is greater than or equal to a reference value, the puncturing level may be reduced. In some implementations, if the error rate is below a reference value, the puncturing level may be increased. In some implementations, the error correction circuit 131a may change the H matrix through parity puncturing corresponding to puncturing option information. In some implementations, the error correction circuit 131a may reduce the puncturing level when the error rate is equal to or greater than the reference value and increase the puncturing level when the error rate is less than the reference value.

The tracking logic 132 may track the memory error rate (e.g., measured by codeword error (CE) count, and/or the like). In some implementations, tracking logic 132 may be activated in a patrol scrub operation. By activating the tracking logic 132 in a patrol scrub operation, additional overhead may be minimized.

Aspects of the present disclosure may provide a solution to the memory aging problem. For example, erroneous data may be moved based on CE count tracking. As illustrated in FIG. 7, erroneous data from the low-reliability memory device 120a may be moved to the high-reliability memory device 110a. For example, when an event (e.g., CE count >threshold) occurs in the tracking logic 132, the control logic circuit 130a can move erroneous data read from the low-reliability memory device 120 to the high-reliability device 110a. In some implementations, the heterogeneous memory device may be configured to read data from a low-reliability memory device, perform an error correction operation on the read data, track a codeword error (CE) count according to the error correction operation, and move the data from the low-reliability memory device to a high-reliability memory device when the CE count value is greater than or equal to a reference value.

In some implementations, the error correction operation is performed using a symbol code. In some implementations, the low-reliability memory device applies a symbol code during a write operation, and the high-reliability memory device applies a Hamming code that varies according to the error rate during a write operation.

In some implementations, before moving the data to a highly reliable memory device, the memory device 100a may notify a host and store the corresponding area in a register/cache within the control logic circuit 130a. The memory device 100a may store the corresponding area inside the control logic circuit 130a by using host driven reliability, availability, and serviceability (RAS). Later, in some implementations, when an event occurs, the memory device 100a may move data to the remaining high-reliability memory area through a demand data scrubbing operation. In this case, demand data scrubbing is an operation that checks data read from memory and corrects the data using ECC if necessary.

The memory device 100a according to some implementations moves erroneous hot data to a highly reliable memory in advance, and may prevent system performance degradation and prevent probable failure.

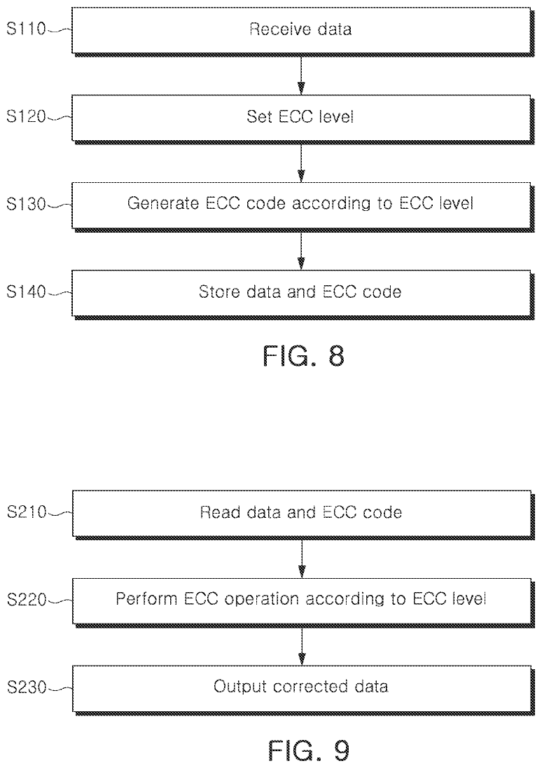

FIG. 8 is a flowchart illustrating an example of the operation of a memory device according to some implementations. For example, the process of FIG. 8 can be performed using the devices of FIGS. 1, 4, and 7 and as described with respect to FIGS. 1-7. The process of FIG. 8 can be used to store write data in a memory.

The memory device may receive write data from a host device (S110), e.g., an external device to which the memory device is connected. An ECC level corresponding to the puncturing option information may be set using a flag/address included in the write data (S120). An ECC code may be generated according to the set ECC level (S130). The write data and the ECC code may be stored in the corresponding memory device (S140).

In some implementations, puncturing option information may be set in a register during an initialization operation. In some implementations, error rates are tracked on data read from different memory devices, and puncturing option information may change according to the tracked error rate. In some implementations, when the error rate is greater than a predetermined value, failure alarm information may be output to the system. In some implementations, when the error rate of data read from the first memory device is greater than or equal to a reference value, erroneous data may be moved internally (without system intervention) to a second memory device that is different from the first memory device. Afterwards, the memory device may notify the system of information related to data movement.

FIG. 9 is a diagram illustrating the operation of a memory device according to some implementations. For example, the process of FIG. 9 can be performed using the devices of FIGS. 1, 4, and 7 and as described with respect to FIGS. 1-7. The process of FIG. 9 can be used to output read data from a memory. The process of FIG. 9 can be performed on data stored according to the process of FIG. 8.

The memory device may read data and ECC code from either the corresponding first memory device or the second memory device in response to an address (S210). The memory device may perform an error correction operation according to the set ECC level corresponding to the selected memory device. The memory device may output error-corrected data to the host (S230). In some implementations, the set ECC level may be changed according to an error rate of the read data. In some implementations, data movement may be performed according to the error rate of the read data.

The present disclosure is applicable to ECC for hybrid memory systems and storage class memory (SCM), to provide two non-limiting examples.

Devices and processes according to the present disclosure may be combined with machine learning-specific memory and processing-in-memory (PIM) technology. Since the present disclosure supports a hybrid memory configuration, it may be used to configure an accelerator for artificial intelligence learning.

Aspects of the present disclosure can be applied to computing systems.

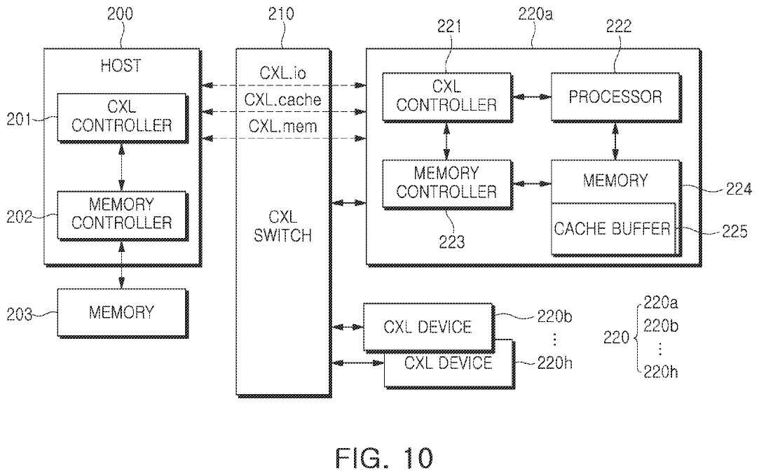

FIG. 10 is a diagram illustrating a computing system according to some implementations. Referring to FIG. 10, a host device 200 and a plurality of CXL devices 220a, 220b, . . . , 220h may communicate with each other through a CXL switch 210. The CXL switch 210 may be a component included in the CXL interface. CXL switch 210 may be configured to mediate communication between the host device 200 and a CXL device 220. For example, when the host device 200 and the CXL device 220 communicate with each other, the CXL switch 210 may be configured to transmit information such as a request, data, response, or signal transmitted from the host device 200 or the CXL device 220 to the CXL device 220 or the host device 200. When the CXL devices 220a, 220b, . . . , 220h communicate with each other, the CXL switch 210 may be configured to transfer information such as requests, data, responses, or signals between the CXL devices 220a, 220b, . . . , 220h.

The host device 200 may include a CXL controller 201. CXL controller 201 may communicate with CXL device 220 through CXL switch 210. CXL controller 201 may be coupled to memory controller 202 and associated memory 203.

The CXL switch 210 may be used to implement a memory cluster through one-to-many and many-to-one switching between connected CXL devices 220a, 220b, . . . , 220h (For example, (i) the CXL switch 210 connects multiple root ports to one endpoint, (ii) connect one root port to multiple endpoints, or (iii) multiple root ports may be connected to multiple endpoints).

In addition to providing packet-switching functionality for CXL packets, the CXL switch 210 may be used to connect CXL devices 220a, 220b, . . . , 220h to one or more host devices 200. The CXL switch 210 (i) allows the CXL devices 220a, 220b, . . . , 220h to include various types of memory with different characteristics, (ii) virtualizes the memories of the CXL devices 220a, 220b, . . . , 220h and allows data of different characteristics (e.g., access frequency) to be stored in an appropriate type of memory, and (iii) supports remote direct memory access (RDMA). In this case, “virtualizing” memory means performing memory address translation between the processing circuitry and the memory.

The CXL device 220a may include a CXL controller 221, a processor 222, a memory controller 223, and a memory device 224. Other CXL devices 220b, . . . , 220h may also include the same or similar components as the CXL device 220a.

The CXL controller 221 may be connected to CXL switch 210. The CXL controller 221 may communicate with the host device 200 or other CXL devices through the CXL switch 210. The CXL controller 221 may include a PCIe 5.0 (or other version) architecture for the CXL.io path, and may add CXL.cache and CXL.mem paths specific to CXL. In some implementations, CXL controller 221 may be configured to be backward compatible with older cache-coherence protocols, such as CXL 1.1. The CXL controller 221 may be configured to implement the CXL.io, CXL.mem and CXL.cache protocols or other suitable cache-consistency protocols. The CXL controller 221 may be configured to support different CXL device types, such as Type 1, Type 2, or Type 3 CXL devices. CXL controller 221 may be configured to support PCIe protocols, such as the PCIe 5.0 protocol. The CXL controller 221 may be configured to support the PIPE 5.x protocol using any suitable PIPE interface width (e.g., 8-bit, 16-bit, 32-bit, 64-bit, and 128-bit configurable PIPE interface widths).

The processor 222 may be configured to control overall operations of the CXL device 220a. The processor 222 may perform operations on data stored in the memory device 224. The processor 222 may perform filtering on data stored in the memory device 224.

The memory controller 223 may control the memory device 224 so that data is stored in the memory device 224 or data is read from the memory device 224. In some implementations, the memory controller 223 may be implemented to comply with standard protocols such as DDR interface, LPDDR interface, and the like. The memory device 224 may store data or output the stored data under the control of the memory controller 223. The memory controller 223 may be configured as described with respect to FIGS. 1-9, e.g., to implement ECC puncturing.

Memory controller 223 may be configured to manage memory device 224. In some implementations, the memory controller 223 may allocate a partial area of the memory device 224 as the cache buffer 225. Memory controller 223 may allocate cache buffer 225 to other devices (e.g., host, other CXL devices).

In some implementations, at least a portion of the area of the memory device 224 of the CXL device 220a may be allocated as a dedicated area for the CXL device 220a, and the remaining area may be used as an accessible area by the host device 200 or other CXL devices 220b, . . . , 220h.

In some implementations, the memory controller 223 may select a data block to be discarded among the data cached in the cache buffer 225 according to the cache replacement policy assigned to the cache buffer 225. As a cache replacement policy, a least recently used (LRU) replacement policy, least frequently used (LFU) replacement policy, re-reference interval prediction (RRIP) replacement policy, and the like may be used. However, in addition to the LRU replacement policy, other cache replacement policies that replace caches according to recency may be used, and in addition to the LFU replacement policy, other cache replacement policies that replace caches according to frequency may be used.

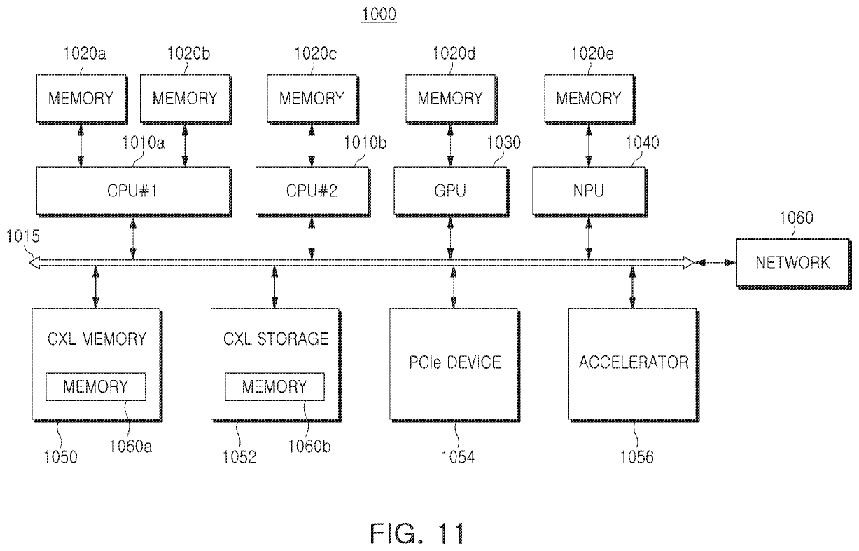

FIG. 11 is a diagram illustrating a computing system 1000 according to some implementations. Referring to FIG. 11, the computing system 1000 includes a first CPU (1010a), a second CPU (1010b), a GPU (1030), an NPU (1040), and may include a CXL switch 1015, CXL memory 1050, CXL storage 1052, a PCIe device 1054, and an accelerator (CXL device) 1056.

The first CPU 1010a, the second CPU 1010b, the GPU 1030, the NPU 1040, the CXL memory 1050, the CXL storage 1052, the PCIe device 1054, and the accelerator 1056 may be commonly connected to the CXL switch 1015, and may respectively communicate with each other via CXL switch 1015. In some implementations, each of the first CPU 1010a, the second CPU 1010b, the GPU 1030, and the NPU 1040 may be a host device, and may respectively be directly connected to individual memories (1020a, 1020b, 1020c, 1020d, 1020c).

In some implementations, the CXL memory 1050 and the CXL storage 1052 may be implemented as a memory device supporting a puncturing option as described in FIGS. 1 to 10.

By one or more of the first CPU (1010a), the second CPU (1010b), the GPU (1030), and the NPU (1040), at least some areas of the memories 1060a and 1060b of the CXL memory 1050 and the CXL storage 1052 may be allocated to at least one cache buffer among a first CPU 1010a, a second CPU 1010b, a GPU 1030, an NPU 1040, a CXL memory 1050, a CXL storage 1052, a PCIe device 1054, and an accelerator 1056.

In some implementations, the CXL switch 1015 may be connected to a PCIe device 1054 or an accelerator 1056 configured to support various functions, and the PCIe device 1054 or accelerator 1056 communicates with each of the first CPU 1010a, the second CPU 1010b, the GPU 1030, and the NPU 1040 through the CXL switch 1015, or may access a CXL memory 1050 and a CXL storage 1052. In some implementations, the CXL switch 1015 may be connected to an external network 1060 or a fabric, and may be configured to communicate with an external server through an external network 1060 or fabric.

Aspects of the present disclosure are applicable to data server systems.

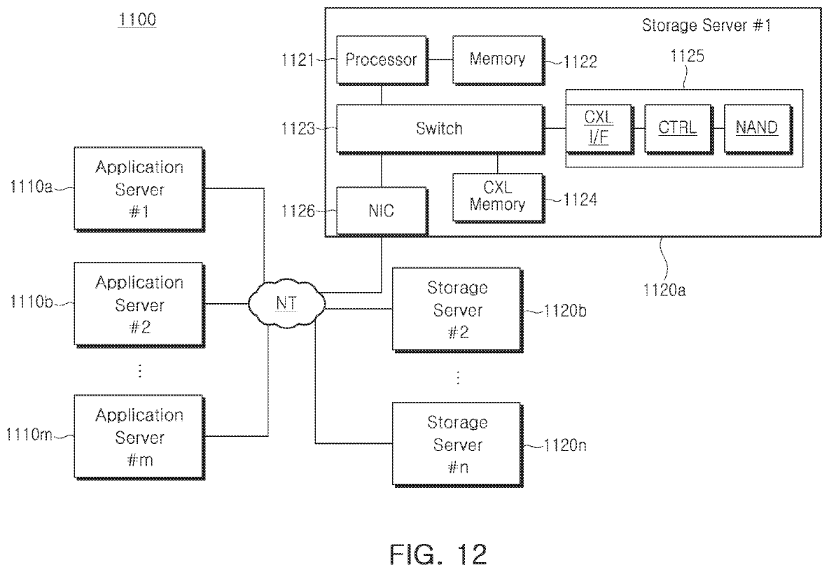

FIG. 12 is a diagram illustrating a data server system 1100 according to some implementations. Referring to FIG. 12, the data server system 1100 is a facility that collects various data and provides services, and may also be referred to as a data storage center. The data server system 1100 may be a system for operating a search engine and database, and may be a computing system used in companies such as banks or government agencies. The data server system 1100 may include application servers 1110a, . . . , 1110h and storage servers 1120a, . . . , 1120h. The number of application servers and the number of storage servers may be selected in various ways according to different implementations, and the number of application servers and the number of storage servers may be different.

Below, the configuration of the first storage server 1120a will be explained in detail. Each of the application servers 1110a, . . . , 1110h and the storage servers 1120a, . . . , 1120h may have a similar structure, and the application servers 1110a, . . . , 1110h and the storage servers 1120a, . . . , 1120h may communicate with each other through the network NT.

The first storage server 1120a may include a processor 1121, memory 1122, switch 1123, storage 1125, CXL memory 1124, and network interface card (NIC) 2216. The processor 1121 may control the overall operation of the first storage server 1120a and access the memory 1122 to execute instructions loaded into the memory 1122 or process data. The processor 1121 and the memory 1122 may be directly connected, and the number of processors 1121 and the number of memories 1122 included in one storage server 1120a may be selected in various ways.

In some implementations, the processor 1121 and the memory 1122 may provide a processor-memory pair. In some implementations, the number of processors 1121 and memories 1122 may be different. The processor 1121 may include a single core processor or a multi-core processor. The above description of the storage server 1120 may be similarly applied to each of the application servers 1110a, . . . , 1110h.

The switch 1123 may be configured to mediate or route communication between various components included in the first storage server 1120a. In some implementations, the switch 1123 may be a CXL switch described in FIGS. 2 and 10, and the like. For example, the switch 1123 may be a switch implemented based on the CXL protocol.

The CXL memory 1124 and the storage device 1125 may be CXL devices capable of configuring ECC according to the puncturing option, as described in FIGS. 1 to 10. The CXL memory 1124 may be connected to switch 1123. The storage device 1125 may include a CXL interface circuit (CXL_IF), a controller (CTRL), and NAND flash (NAND). The storage device 1125 may store data or output the stored data according to a request from the processor 1121. Application servers 1110a, . . . , 1110h may not include storage 1125.

A network interface card (NIC) 1126 may be connected to the CXL switch 1123. The NIC 1126 may communicate with other storage servers 1120a, . . . , 1120h or other application servers 1110a, . . . , 1110h through a network (NT). In some implementations, the NIC 1126 may include a network interface card, a network adapter, and the like. The NIC 1126 may be connected to the network NT by a wired interface, a wireless interface, a Bluetooth interface, an optical interface, and the like. The NIC 1126 may include internal memory, a digital signal processor (DSP), a host bus interface, and the like, and may be connected to the processor 1121 or switch 1123 through a host bus interface. In some implementations, the NIC 1126 may be integrated with at least one of the processor 1121, the switch 1123, and the storage device 1125.

In some implementations, the network (NT) may be implemented using Fiber Channel (FC) or Ethernet. At this time, FC is a medium used for relatively high-speed data transmission, and may use optical switches that provide high performance/high availability. According to the network (NT) access method, storage servers may provide file storage, block storage, or object storage.

In some implementations, the network NT may be a storage-only network, such as a storage area network (SAN). For example, the SAN may be an FC-SAN that uses an FC network and is implemented according to the FC Protocol (FCP). As another example, the SAN may be an IP-SAN that uses a TCP/IP network and is implemented according to the iSCSI (SCSI over TCP/IP or Internet SCSI) protocol. In some implementations, the network NT may be a general network such as a TCP/IP network. For example, the network (NT) may be implemented according to protocols such as FC over Ethernet (FCOE), Network Attached Storage (NAS), and NVMe over Fabrics (NVMe-oF).

In some implementations, at least one of the application servers 1110a, . . . , 1110h may store data requested by a user or client to be stored in one of the storage servers 1120a, . . . , 1120h through the network NT. At least one of the application servers 1110a, . . . , and 1110h may obtain data requested by a user or client to be read from one of the storage servers 1120a, . . . , 1120h through the network NT. For example, at least one of the application servers 1110a, . . . , 1110h may be implemented as a web server or a DBMS (Database Management System).

In some implementations, at least one of the application servers 1110a, . . . , 1110h may access memory, CXL memory, or a storage device included in another application server through the network NT, or may access the memories, CXL memories, or storage devices included in the storage servers 1120a, . . . , 1120h through the network (NT). Accordingly, at least one of the application servers 1110a, . . . , 1110h may perform various operations on data stored in other application servers or storage servers. For example, at least one of the application servers 1110a, . . . , 1110h may execute a command to move or copy data between other application servers or storage servers. At this time, data may be moved from the storage devices of the storage servers through the memories or CXL memories of the storage servers, or directly to the memory or CXL memory of the application servers. Data moving over the network may be encrypted for security or privacy.

In some implementations, each component or a combination of two or more components described with reference to FIGS. 1 to 12 may be implemented as a digital circuit, programmable or non-programmable logic device or array, application specific integrated circuit (ASIC), and the like.

The device described above may be implemented with hardware components, software components, or a combination of hardware components and software components. For example, the devices and components described in the above examples may be implemented using one or more general-purpose computers or special-purpose computers, such as a processor, controller, arithmetic logic unit (ALU), digital signal processor, microcomputer, field programmable gate array (FPGA), programmable logic unit (PLU), microprocessor, or any other devices that may execute and respond to instructions. The processing device may execute an operating system (OS) and one or more software applications running on the operating system. Additionally, a processing device may access, store, manipulate, process, and generate data in response to the execution of software. For ease of understanding, the processing unit may be described as being used in some cases, but those skilled in the art will appreciate that a processing device may include a plurality of processing elements or multiple types of processing elements. For example, a processing device may include a plurality of processors or one processor and one controller. Additionally, other processing configurations, such as parallel processors, are also possible.

Software may include computer programs, code, instructions, or a combination of one or more thereof, and may configure processing units to operate as desired or command the processing units independently or collectively. Software or data may be embodied in any type of machine, component, physical device, virtual equipment, computer storage medium, or device, to be interpreted by or to provide instructions or data to a processing device. Software may be distributed over networked computing systems and thus stored or executed in a distributed manner. Software and data may be stored on one or more computer-readable recording media.

The memory devices of the present disclosure may support a hybrid memory system by configuring one ECC circuit using ECC puncturing, rather than configuring an independent ECC. By adjusting the puncturing level, the memory devices of the present disclosure may adjust the ECC level for volatile-fast memory.

As set forth above, an error correction code may be generated according to a puncturing option during a write operation, and thus, overall system may be improved by reducing unnecessary memory usage.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While several examples have been illustrated and described above, it will be apparent to those skilled in the art that modifications and variations could be made without departing from the scope of the present disclosure.

1. A memory device comprising:
a first memory device;
a second memory device; and
a control logic circuit configured to control the first memory device and the second memory device,
wherein the control logic circuit includes an error correction circuit configured to generate, based on puncturing option information,
a first error correction code of a first size, and
a second error correction code of a second size, wherein the second size is larger than the first size, and
wherein the control logic circuit is configured to store the first error correction code in the first memory device during a first write operation, and store the second error correction code in the second memory device during a second write operation.

2. The memory device of claim 1, wherein the first memory device is configured to apply a punctured error correction code, and
the second memory device is configured to apply an original error correction code.

3. The memory device of claim 1, wherein the first memory device is a volatile memory device, and
wherein the second memory device is a non-volatile memory device.

4. The memory device of claim 1, wherein the control logic circuit is configured to variably set the first size based on an error rate of data stored in the first memory device.

5. The memory device of claim 1, wherein the puncturing option information is set in a register during an initialization operation.

6. The memory device of claim 1, wherein the error correction circuit is configured to change the puncturing option information in real-time.

7. The memory device of claim 1, wherein the error correction circuit is configured to vary the puncturing option information based on an error rate of read data.

8. The memory device of claim 7, wherein the error correction circuit is configured to vary the puncturing option information an error rate range.

9. The memory device of claim 1, wherein the error correction circuit is configured to change settings of an encoder/decoder based on the puncturing option information.

10. The memory device of claim 1, wherein the error correction circuit is configured to change at least one of a type of error correction code or an H matrix based on the puncturing option information.

11. A memory device comprising:
a first memory device;
a second memory device; and
a control logic circuit configured to control the first memory device and the second memory device,
wherein the control logic circuit includes
an error correction circuit configured to generate a punctured error correction code for the first memory device or an original error correction code for the second memory device based on puncturing option information, and
a tracking logic configured to track an error rate of data read from the first memory device or the second memory device,
wherein the puncturing option information is changed based on the error rate.

12. The memory device of claim 11, wherein the memory device is configured to communicate with an external device using a Compute Express Link (CXL) interface,
the punctured error correction code is a Hamming code,
the original error correction code is an RS code, and
the control logic circuit is configured to move erroneous data from the second memory device to the first memory device based on the error rate.

13. The memory device of claim 11, wherein the error correction circuit is configured to change an H matrix through parity puncturing based on the puncturing option information.

14. The memory device of claim 11, wherein the error correction circuit is configured to reduce a puncturing level when the error rate is at least a reference value, and to increase the puncturing level when the error rate is less than the reference value.

15. The memory device of claim 11, wherein the control logic circuit is configured to active the tracking logic during a patrol scrub operation.

16. A method of operating a memory device, the method comprising:
receiving write data;
setting an error correction code level based on puncturing option information;
generating an error correction code for the write data based on the error correction code level; and
storing the write data and the error correction code in a first memory device corresponding to the error correction code level.

17. The method of claim 16, further comprising setting the puncturing option information in a register in an initialization operation.

18. The method of claim 16, further comprising:
tracking an error rate on data read from the first memory device; and
changing the puncturing option information based on the error rate.

19. The method of claim 18, further comprising outputting failure alarm information to a system in response to the error rate being greater than a predetermined value.

20. The method of claim 16, further comprising moving erroneous data to a second memory device different from the first memory device in response to an error rate of data read from the first memory device being greater than or equal to a reference value.

21.-30. (canceled)
